(19) United States
(12) Patent Application Publication
(10) Pub. No.: US 2024/0322096 A1
(43) Pub. Date: Sep. 26, 2024

(54) LED DISPLAY DEVICE

(71) Applicant: FUJIFILM Corporation, Tokyo (JP)

(72) Inventors: Wakahiko KANEKO, Minamiashigara-shi (JP); Wataru MAJIMA, Minamiashigara-shi (JP); Tatsuya OBA, Minamiashigara-shi (JP)

(73) Assignee: FUJIFILM Corporation, Tokyo (JP)

(21) Appl. No.: 18/735,833

(22) Filed: Jun. 6, 2024

Related U.S. Application Data
(63) Continuation of application No. PCT/JP2022/046033, filed on Dec. 14, 2022.

(30) Foreign Application Priority Data
Dec. 22, 2021 (JP) 2021-207946

(51) Int. Cl. H01L 33/60; H01L 25/16; H01L 33/50

(52) U.S. Cl. CPC H01L 33/60; H01L 25/167; H01L 33/505

(57) ABSTRACT

Provided is an LED display device that can improve utilization efficiency of light with a simple configuration having a small number of components. The LED display device includes an LED array formed by arranging a plurality of light emitting diodes that emit excitation light having a wavelength of less than 420 nm, on a substrate; a color conversion layer; a wavelength-selective reflection layer disposed on a side opposite to the LED array; and an RGB reflection layer disposed on an LED array side with respect to the color conversion layer, in which the color conversion layer is disposed at each of positions corresponding to the light emitting diodes of the LED array, and includes a red color conversion region emitting red light, a green color conversion region emitting green light, and a blue color conversion region emitting blue light, which are excited by the excitation light, and a partition wall that divides each region, a height h of the partition wall is 20 μm or less and a ratio w/h of a width w between partition walls to the height h is 2 or more, the wavelength-selective reflection layer selectively reflects light having a wavelength of the excitation light and is integrally formed at positions corresponding the respective regions, and the RGB reflection layer reflects at least light having a wavelength of 450 nm to 650 nm.

### CROSS-REFERENCE TO RELATED APPLICATIONS

This application is a Continuation of PCT International Application No. PCT/JP2022/046033 filed on Dec. 14, 2022, which claims priority under 35 U.S.C. § 119(a) to Japanese Patent Application No. 2021-207946 filed on Dec. 22, 2021. The above applications are hereby expressly incorporated by reference, in their entirety, into the present application.

### BACKGROUND OF THE INVENTION

### 1. Field of the Invention

The present invention relates to an LED display device.

### 2. Description of the Related Art

An LED display device that includes a color conversion layer (color conversion layer, wavelength conversion layer) of each color of red, green, and blue, and displays an image by exciting the color conversion layer of each color of red, green, and blue with excitation light emitted, as a light emitting diode (LED) as an excitation light source, by the LED, and emitting light has been disclosed.

Light emitted by the wavelength conversion layer being excited is emitted in various directions without depending on an incidence direction or the like of the excitation light. Therefore, only a part of the light emitted from the wavelength conversion layer is emitted from a display surface of the LED display device, and remaining light is, for example, absorbed by a partition wall that divides the wavelength conversion layer of each color or emitted to an LED side, and is not emitted from the display surface of the LED display device. Therefore, there is a problem that utilization efficiency of light is poor.

Regarding the above, it has been proposed that a reflection layer that reflects the wavelength-converted light on the LED side is disposed on a wavelength conversion layer side to reflect the light incident on the LED side toward a display surface side of the LED display device, thereby increasing the utilization efficiency of light.

In addition, it has been proposed that a reflection layer that reflects the excitation light is disposed on an emission side of the wavelength conversion layer, and the excitation light transmitted through the wavelength conversion layer is incident on the wavelength conversion layer again to increase conversion efficiency of light.

For example, JP2020-145425A discloses an image display element comprising: a plurality of LED elements that are mounted on a drive circuit board and that emit light source light; a wavelength conversion layer that is laminated on a side opposite to the drive circuit board with the plurality of LED elements and converts the light source light emitted by the plurality of LED elements into long-wavelength light and emits the long-wavelength light on the side opposite to the drive circuit board; and a first functional layer that is provided on a side of a light emission surface of long-wavelength light of the wavelength conversion layer, reflects the light source light, and transmits the long-wavelength light.

In addition, JP2020-145425A discloses that the wavelength conversion layer comprises a second functional layer that is provided on a side of a light incidence surface of the light source light and reflects the long-wavelength light.

### SUMMARY OF THE INVENTION

Here, in JP2020-145425A, the first functional layer that reflects the light source light and transmits the long-wavelength light and the second functional layer that reflects the long-wavelength light are provided by being divided into a plurality of LED elements. In this way, by dividing the first functional layer and the second functional layer for each LED element, it is possible to prevent crosstalk in which light leaks to an adjacent wavelength conversion layer (subpixel) as a functional layer serves as a light guide path.

However, a configuration in which the first functional layer and the second functional layer are divided for each LED element has a problem that the number of components is large, a structure is complicated, and the number of manufacturing processes is large.

An object of the present invention is to solve such a problem, and to provide an LED display device in which the utilization efficiency of light can be improved with a simple configuration having a small number of components.

The present invention solves the problem by following configurations.

[1] An LED display device comprising:
an LED array formed by arranging a plurality of light emitting diodes that emit excitation light having a light emission peak wavelength of less than 420 nm, on a substrate;
a color conversion layer;
a wavelength-selective reflection layer disposed on a side of the color conversion layer opposite to the LED array; and
an RGB reflection layer disposed on an LED array side with respect to the color conversion layer,
in which the color conversion layer is disposed at each of positions corresponding to the light emitting diodes of the LED array, and includes a red color conversion region that is excited by the excitation light and emits red light, a green color conversion region that is excited by the excitation light and emits green light, a blue color conversion region that is excited by the excitation light and emits blue light, and a partition wall that divides the red color conversion region, the green color conversion region, and the blue color conversion region,
a height h of the partition wall is 20 μm or less and a ratio w/h of a width w between partition walls to the height h is 2 or more,
the wavelength-selective reflection layer selectively reflects light having a wavelength of the excitation light and is integrally formed at positions corresponding to the red color conversion region, the green color conversion region, and the blue color conversion region, and
the RGB reflection layer reflects at least light having a wavelength of 450 nm to 650 nm.

[2] The LED display device according to [1],
in which the RGB reflection layer is disposed between the color conversion layer and the LED array, and
the RGB reflection layer transmits the excitation light.

[3] The LED display device according to [1],
in which the RGB reflection layer is disposed on at least a part of a position other than a region, in which the light emitting diode is disposed, on a surface of the substrate on which the light emitting diode is disposed, and
the RGB reflection layer reflects at least light having a wavelength of 380 nm to 650 nm.

[4] The LED display device according to any one of [1] to [3],
in which a thickness of the wavelength-selective reflection layer is 5 um or less.

[5] The LED display device according to any one of [1] to [4],
in which a thickness of the RGB reflection layer is 40 um or less.

[6] The LED display device according to any one of [1] to [5],
in which an interval between the wavelength-selective reflection layer and the partition wall in a thickness direction is 5 μm or less.

According to the present invention, it is possible to provide an LED display device that can improve the utilization efficiency of light with a simple configuration having a small number of components.

### BRIEF DESCRIPTION OF THE DRAWINGS

FIG. 1 is a diagram conceptually showing an example of a configuration of an LED display device according to an embodiment of the present invention.

FIG. 2 is a top view conceptually showing a color conversion layer included in the LED display device shown in FIG. 1.

FIG. 3 is a diagram conceptually showing another example of the LED display device according to the embodiment of the present invention.

FIG. 4 is a diagram schematically showing a configuration of an LED display device according to an example of the present invention.

FIG. 5 is a diagram for describing a manufacturing process of the LED display device shown in FIG. 4.

FIG. 6 is a diagram schematically showing another configuration of the LED display device according to an example of the present invention.

FIG. 7 is a diagram for describing a manufacturing process of the LED display device shown in FIG. 6.

FIG. 8 is a diagram schematically showing another configuration of the LED display device according to an example of the present invention.

FIG. 9 is a diagram for describing a manufacturing process of the LED display device shown in FIG. 8.

FIG. 10 is a diagram schematically showing an example of a configuration of a LED display device in the related art.

FIG. 11 is a diagram for describing a manufacturing process of the LED display device shown in FIG. 10.

FIG. 12 is a diagram for describing a leaking-light distance.

### DESCRIPTION OF THE PREFERRED EMBODIMENTS

Hereinafter, an embodiment of the present invention will be specifically described. In the present specification, a numerical range represented using “to” means a range including numerical values described before and after the preposition “to” as a lower limit value and an upper limit value.

Further, in the present specification, the term “(meth)acrylate” is a notation expressing both acrylate and methacrylate, the term “(meth)acryloyl group” is a notation expressing both acryloyl group and methacryloyl group, and the term “(meth)acrylic” is a notation expressing both acrylic and methacrylic.

In the present specification, the meanings of terms such as “identical” and “the same” may include a range of errors generally accepted in the technical field. In addition, in the present specification, the term such as “identical” and “the same” with regard to an angle means that, unless otherwise specified, a difference from an exact angle is within a range of less than 5 degrees. The difference from the exact angle is preferably less than 4 degrees and more preferably less than 3 degrees.

### [LED Display Device]

The LED display device according to the embodiment of the present invention is an LED display device including:
an LED array formed by arranging a plurality of light emitting diodes that emit excitation light having a light emission peak wavelength of less than 420 nm, on a substrate;
a color conversion layer;
a wavelength-selective reflection layer disposed on a side of the color conversion layer opposite to the LED array; and
an RGB reflection layer disposed on an LED array side with respect to the color conversion layer,
in which the color conversion layer is disposed at each of positions corresponding to the light emitting diodes of the LED array, and includes a red color conversion region that is excited by the excitation light and emits red light, a green color conversion region that is excited by the excitation light and emits green light, a blue color conversion region that is excited by the excitation light and emits blue light, and a partition wall that divides the red color conversion region, the green color conversion region, and the blue color conversion region,
a height h of the partition wall is 20 μm or less and a ratio w/h of a width w between partition walls to the height h is 2 or more,
the wavelength-selective reflection layer selectively reflects light having a wavelength of the excitation light and is integrally formed at positions corresponding to the red color conversion region, the green color conversion region, and the blue color conversion region, and
the RGB reflection layer reflects at least light having a wavelength of 450 nm to 650 nm.

Hereinafter, the LED display device according to an embodiment of the present invention will be described with reference to the accompanying drawings.

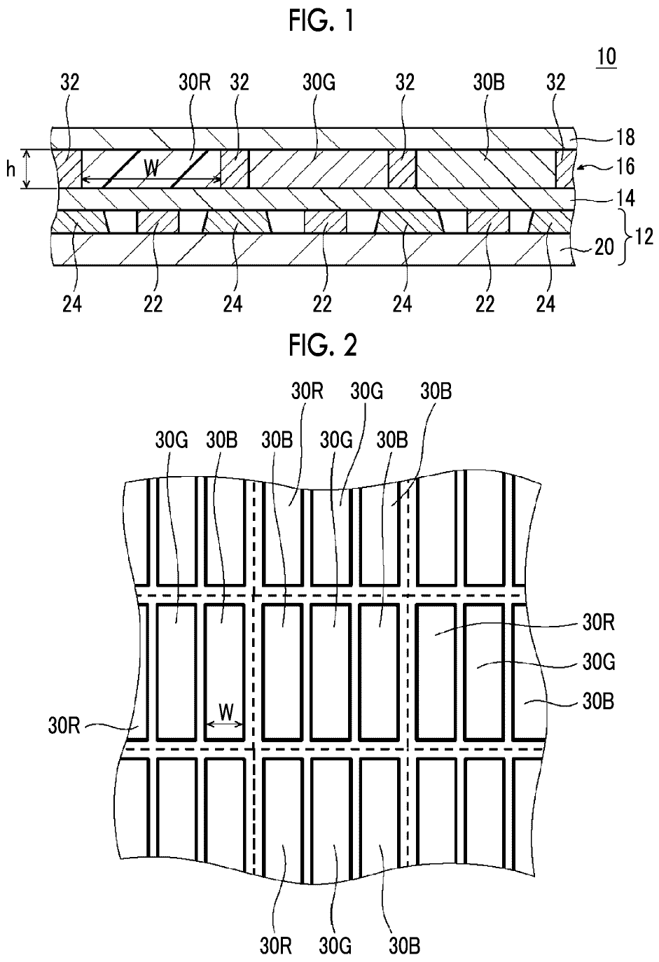

FIG. 1 is a diagram conceptually showing an example of a configuration of a light emitting diode (LED) display device according to the embodiment of the present invention.

An LED display device 10 shown in FIG. 1 includes an LED array 12, an RGB reflection layer 14, a color conversion layer 16, and a wavelength-selective reflection layer 18 in this order.

### <LED Array>

The LED array 12 is formed by two-dimensionally arranging a plurality of light emitting diodes (hereinafter, also referred to as LEDs) 22 on a substrate 20. In addition, in the example shown in FIG. 1, the LED array 12 has an element separation region (bank) 24 between the LEDs 22.

### (Substrate)

The substrate 20 is a circuit board that is provided with the plurality of LEDs 22 and drives the disposed LEDs 22, and includes, for example, a glass base material, a wiring layer provided on the base material, a thin film transistor (TFT) circuit for driving, and an electrode. Instead of the TFT circuit, another drive element, for example, a complementary MOS (CMOS)-integrated circuit (IC) chip may be provided. Alternatively, a display device 1 may be driven by a passive matrix.

As the substrate 20, various substrates used as a substrate for supporting an LED in a known LED display device can be appropriately used. A circuit that drives the LED 22 is provided on the substrate 20. Therefore, the substrate 20 is preferably an insulating substrate on which a wiring line can be formed, and for example, a heat-resistant resin film such as a polyimide film, a glass substrate such as alkali-free glass, or a silicon substrate can be used.

A thickness of the substrate 20 is not particularly limited as long as the LED 22 can be supported, but from the viewpoint of thinning or the like of the LED display device, the thickness is preferably 1.5 μm to 0.3 μm and more preferably 1.1 μm to 0.3 μm.

### (Light Emitting Diode)

The LED 22 is a light emitting diode that emits ultraviolet light (UV light) having a light emission peak wavelength of less than 420 nm. UV light emitted by the LED 22 is excitation light that excites the color conversion layer 16.

The plurality of LEDs 22 are two-dimensionally arranged in a matrix on one surface of the substrate 20. Specifically, the plurality of LEDs 22 are disposed, for example, individually at a position of each subpixel described later. That is, an arrangement interval or the like of the LED 22 need only be set according to the position of each subpixel.

The LED 22 is not limited as long as light having a light emission peak wavelength of less than 420 nm is emitted, and various LEDs used in a known LED display device can be appropriately used. The LED 22 may be a so-called micro LED. For example, as the LED 22, an LED that emits excitation light having a peak wavelength of 385 nm is used.

The LED 22 has, for example, a planar shape of a quadrangle. A size of one side of the quadrangle is preferably 1 μm or more and 100 μm or less. In addition, the LED 22 has, for example, a three-dimensional shape such as a substantially rectangular parallelepiped shape or a substantially cubic shape.

The element separation region (bank) 24 is disposed around the LED 22, and includes a light shielding material and a resin material that do not transmit light having a wavelength of 360 to 650 nm, in order to prevent the excitation light emitted by the LED 22 from leaking to an adjacent subpixel, the color conversion layer 16, or the like. The light shielding material is, for example, a black pigment or a black dye. Alternatively, a surface may be colored white so as to reflect light, or a metal may be disposed to reflect light.

The bank (element separation region) 24 is formed of, for example, a black photosensitive material forming a black matrix.

### <Color Conversion Layer>

The color conversion layer 16 has a wavelength conversion function of being excited by the excitation light emitted by the LED 22 and emitting light having a wavelength different from that of the excitation light.

In the present invention, the color conversion layer 16 has a plurality of conversion regions that emit light having different wavelengths corresponding to respective pixels. Specifically, as in the example shown in FIG. 1, the color conversion layer 16 has a plurality of red color conversion regions 30R that are excited by the excitation light and emit red light, a plurality of green color conversion regions 30G that are excited by the excitation light and emit green light, and a plurality of blue color conversion regions 30B that are excited by the excitation light and emit blue light, in a plane direction. In addition, in the example shown in FIG. 1, a partition wall (black matrix) 32 that divides each conversion region is provided.

FIG. 2 shows a top view of the color conversion layer 16.

As shown in FIG. 2, the red color conversion region 30R, the green color conversion region 30G, and the blue color conversion region 30B have substantially square shapes in a plan view, and are arranged in a left-right direction in the drawing in an order of the red color conversion region 30R, the green color conversion region 30G, and the blue color conversion region 30B. In addition, in an up-down direction in the drawing, the same type of conversion regions (hereinafter, also referred to as a wavelength conversion region or a color conversion region) are arranged.

In FIG. 2, a set of the red color conversion region 30R, the green color conversion region 30G, and the blue color conversion region 30B, which is surrounded by broken lines and which is continuous in the left-right direction in the drawing, each corresponds to one pixel, and each conversion region corresponds to a subpixel.

As each conversion region, various known color conversion layers (wavelength conversion layers) can be used, which are formed by dispersing phosphor that converts the light emitted from the LED 22 into light in a red wavelength range, a green wavelength range, or a blue wavelength range in a matrix of a curable resin or the like. For example, in a case where the excitation light from the LED 22 is incident on each conversion region, cach conversion region converts a wavelength of at least a part of the excitation light into red light, green light, or blue light by an effect of the phosphor contained therein to emit the light. As described above, an excitation wavelength for exciting cach conversion region is within an ultraviolet region.

Here, the blue light is light having a light emission center wavelength within a wavelength range of 400 nm or more and 500 nm or less, the green light is light having a light emission center wavelength within a wavelength range of more than 500 nm and 600 nm or less, and the red light is light having a light emission center wavelength within a wavelength range of more than 600 nm and 680 nm or less.

### (Phosphor)

The phosphor emits at least fluorescence by being excited by the incident excitation light.

A type of the phosphor contained in the conversion region is not particularly limited, and various types of known phosphor may be appropriately selected according to the required wavelength conversion performance or the like.

Examples of such phosphor include a phosphor in which rare earth ions are doped in a phosphate, an aluminate, a metal oxide, or the like, a phosphor in which an activating ion is doped in a semiconductor material such as a metal sulfide or a metal nitride, and a phosphor using a quantum confinement effect known as a quantum dot, in addition to an organic fluorescent dye and an organic fluorescent pigment. Among these, the quantum dot having a narrow emission spectrum width and excellent color reproducibility in a case of being used in a display, and having an excellent light emission quantum efficiency is suitably used in the present invention.

With respect to the quantum dot, reference can be made to, for example, paragraphs 0060 to 0066 of JP2012-169271A, but the quantum dot is not limited to that described therein. In addition, a commercially available product can be used without any limitation as the quantum dot. A luminescence wavelength of the quantum dot can usually be adjusted by a composition and a size of a particle.

The phosphor is preferably uniformly dispersed in the matrix, but may be dispersed with a bias in the matrix. In addition, only one type of phosphor may be used or of two or more types of phosphor may be used in combination.

In a case where two or more types of phosphor are used in combination, two or more types of phosphor having different wavelengths of the emission light may be used.

In addition, as the quantum dot, a so-called quantum rod having a rod-like shape and having directivity and emitting polarized light or a tetrapod-shaped quantum dot may be used.

In addition, various known matrices used in a color conversion layer (conversion region) can be used as the matrix. Suitable matrix materials include, but are not limited to, epoxy, acrylate, norbornene, polyethylene, poly (vinyl butyral); poly (vinyl acetate), polyurea, polyurethane; silicone and silicone derivatives including, but not limited to, aminosilicone (AMS), polyphenylmethylsiloxane, polyphenylalkylsiloxane, polyphenylsiloxane, polydialkylsiloxane, silsesquioxane, fluorosilicone, and vinyl and hydride-substituted silicone; acrylic polymers and copolymers formed from monomers including, but not limited to, methyl methacrylate, butylmethacrylate, and lauryl methacrylate; styrene-based polymers such as polystyrene, amino polystyrene (APS), and poly (acrylonitrile ethylene-styrene) (AES); a polymer crosslinked with a difunctional monomer such as divinylbenzene; epoxide bonded to a crosslinking agent suitable for crosslinking with a ligand material and ligand amine (for example, APS or PEI ligand amine) to form epoxy.

In addition, as the matrix of the conversion region, a polymerizable composition (coating composition) containing two or more types of polymerizable compounds may be cured.

The matrix forming the conversion region, in other words, the polymerizable composition to be the conversion region may contain necessary components such as a viscosity adjuster and a solvent, as necessary. The polymerizable composition to be the conversion region is, in other words, a polymerizable composition for forming the conversion region.

In the conversion region, an amount of the resin to be the matrix may be appropriately determined according to a type or the like of a functional material included in the conversion region.

A thickness of the conversion region may also be appropriately determined according to a type, a use, or the like of the conversion region. In a case where the conversion region contains the quantum dot, from the viewpoint of handleability and light emission characteristics, the thickness of the conversion region is preferably 5 to 200 μm, and more preferably 10 to 150 μm.

The above-described thickness of the conversion region is intended to be an average thickness, and the average thickness is obtained by measuring thicknesses of any 10 or more points in the conversion region and arithmetically averaging the measured values.

A polymerization initiator, a silane coupling agent, or the like may be added to the polymerizable composition to be the conversion region, as necessary.

The partition wall 32 is provided at a position corresponding to the element separation region 24, is formed of a material that does not transmit light having a wavelength of 360 nm to 650 nm, and is provided as a partition wall that separates the conversion regions that emit light in wavelength ranges different from each other to perform light shielding.

The partition wall 32 can prevent light leak to an adjacent region and can improve the contrast of the display device 1. A surface of the partition wall 32 may be made white to reflect light, or metal may be disposed to reflect light, but in this case, external light is reflected, so that the contrast is lowered. Therefore, it is desirable to take measures such as disposing a circular polarization plate for preventing reflection on a visible side or forming a black matrix layer for preventing reflection on an upper surface of the partition wall 32.

As a material for forming the partition wall 32, a material known in the related art can be used. Specifically, as the material for forming the partition wall 32, a composition obtained by mixing and dispersing a pigment or a dye, which consists of a metal oxide such as carbon black, titanium black, an iron oxide, a titanium oxide, silver tin, a silver oxide, and a titanium oxide, or a mixture thereof, in a resin binder can be used.

Examples of a commercially available product of the titanium black include titanium black 10S, 12S, 13R, 13M, 13M-C, 13R, and 13R-N manufactured by Mitsubishi Materials Corporation, and Tilack D manufactured by AKO KASEI CO., LTD.

A height h of the partition wall is desirably as low as possible from the viewpoint of light extraction efficiency.

Here, in the present invention, the height h of the partition wall is 20 μm or less, and a ratio w/h of a width (width of the conversion region) w between the partition walls to the height h is 2 or more. As shown in FIG. 2, in a case where the shape of the conversion region in the plan view is a substantially rectangular shape, a short side is set to the width w between the partition walls.

This point will be described in detail later.

### <Wavelength-Selective Reflection Layer>

The wavelength-selective reflection layer 18 is an excitation light reflection layer that selectively reflects light having a wavelength of the excitation light, and is disposed on a side of the color conversion layer 16 opposite to the LED array 12, that is, on an emission side. Specifically, for example, the wavelength-selective reflection layer 18 selectively reflects light having a wavelength of less than 420 nm, which is the excitation light, and transmits at least light having a wavelength of 450 nm to 650 nm, which is light having a wavelength at which cach conversion region emits light.

By disposing the wavelength-selective reflection layer 18 that reflects the excitation light on the emission side of the color conversion layer 16 and transmits the light having the wavelength at which each conversion region emits light, the excitation light, which is incident on the color conversion layer 16 and is transmitted through the color conversion layer 16 without being converted, is incident on the color conversion layer again, so that conversion efficiency of light can be increased.

In addition, since the wavelength-selective reflection layer 18 transmits light having a wavelength at which each conversion region of the color conversion layer 16 is excited and emits light, light emitted from each conversion region can be emitted from the LED display device 10.

In addition, the wavelength-selective reflection layer 18 is disposed at positions corresponding to the red color conversion region 30R, the green color conversion region 30G, and the blue color conversion region 30B in the plane direction, and the wavelength-selective reflection layer 18 at each position is integrally formed. That is, the wavelength-selective reflection layer 18 is disposed to cover the red color conversion region 30R, the green color conversion region 30G, and the blue color conversion region 30B, and is also disposed on the partition wall that divides each conversion region. The wavelength-selective reflection layer 18 has the same characteristics for reflection and transmission at a position corresponding to the red color conversion region 30R, a position corresponding to the green color conversion region 30G, and a position corresponding to the blue color conversion region 30B. Therefore, the wavelength-selective reflection layer 18 transmits light having a wavelength at which the red color conversion region 30R emits light, light having a wavelength at which the green color conversion region 30G emits light, and light having a wavelength at which the blue color conversion region 30B cmits light.

The wavelength-selective reflection layer 18 may be integrally formed on the color conversion layer 16. In that case, in a case where a thickness of the wavelength-selective reflection layer 18 is increased, the reflected excitation light may leak into an adjacent region and cause color mixing. Therefore, the thickness is desirably as small as possible, preferably 10 μm or less, more preferably 5 μm to 1 μm, and still more preferably 3 μm to 1 μm.

In the present invention, the fact that the wavelength-selective reflection layer 18 and the RGB reflection layer 14 reflect light having a certain wavelength means that the reflectivity at the wavelength is 60% or more, preferably 70% or more, and more preferably 80% or more. In addition, the fact that the wavelength-selective reflection layer 18 and the RGB reflection layer 14 transmit light having a certain wavelength means that the light transmittance at the wavelength is 60% or more, preferably 70% or more, and more preferably 80% or more.

As the wavelength-selective reflection layer that selectively reflects the excitation light, a cholesteric liquid crystal layer formed by fixing a cholesteric liquid crystalline phase or a laminate in which a layer of high refractive index and a layer of low refractive index are alternately laminated in a plurality of layers (so-called dielectric multi-layer film) is suitably used.

### <<Dielectric Multi-Layer Film>>

The dielectric multi-layer film has a configuration in which a layer of low refractive index and a layer of high refractive index are alternately laminated.

It is known that a film in which a layer having a low refractive index (layer of low refractive index) and a layer having a high refractive index (layer of high refractive index) are alternately laminated reflects light having a specific wavelength because of constructive interference between a plurality of layers of low refractive index and layers of high refractive index.

The wavelength at which the dielectric multi-layer film reflects and the reflectivity of the dielectric multi-layer film can be adjusted by a difference in refractive indices between the layer of low refractive index and the layer of high refractive index, a thickness, layers to be laminated, and the like. Specifically, a thickness d of the layer of low refractive index and the layer of high refractive index is set to d=N(4×n) based on a wavelength λ of light to be reflected and a refractive index n. Accordingly, the wavelength λ of the light to be reflected can be adjusted. In addition, the reflectivity can be adjusted by adjusting the number of layers because the reflectivity increases as the number of lamination of the layers of low refractive index and the layers of high refractive index increases. Furthermore, a width of a reflection band can be adjusted by a difference in refractive indices between the layer of low refractive index and the layer of high refractive index, a thickness, layers to be laminated, and the like.

Therefore, in a case where the dielectric multi-layer film is used as the wavelength-selective reflection layer that reflects the excitation light, a difference in refractive indices between the layer of low refractive index and the layer of high refractive index, a thickness, layers to be laminated, and the like need only be adjusted such that a selective reflection center wavelength of the dielectric multi-layer film is within a range including the wavelength of the excitation light.

Here, the bandwidth of a reflection peak in the dielectric multi-layer film depends on a difference between the refractive index of the layer of high refractive index and the refractive index of the layer of low refractive index, and the band width is larger as the difference in refractive index is larger. Therefore, by adjusting a difference between the refractive index of the layer of high refractive index and the refractive index of the layer of low refractive index to adjust the bandwidth of the reflection peak in the dielectric multi-layer film, the reflection bandwidth of the wavelength-selective reflection layer can be adjusted (broadened).

Examples of a material that is particularly suitably used as the dielectric multi-layer film include polyethylene naphthalate (PEN) and polyethylene terephthalate (PET) as the layer of high refractive index, and PEN, PET, and polymethyl methacrylate resin (PMMA) as the layer of low refractive index.

The dielectric multi-layer film can be formed by a known method in the related art, such as stretching and extrusion molding.

### <<Cholesteric Liquid Crystal Layer>>

The cholesteric liquid crystal layer means a layer with a cholesteric liquid crystalline phase fixed. The cholesteric liquid crystal layer need only be a layer in which the alignment of a liquid crystal compound serving as the cholesteric liquid crystalline phase is maintained. For example, the cholesteric liquid crystal layer is a layer obtained according to the following procedure: a polymerizable liquid crystal compound is set in an alignment state of the cholesteric liquid crystalline phase; ultraviolet irradiation, heating, or the like is carried out to polymerize and cure the compound. The cholesteric liquid crystal layer is preferably a layer that has no fluidity and that has been changed to a state in which the alignment state is not changed by an external field or an external force.

The cholesteric liquid crystal layer is not particularly limited as long as the optical characteristics of the cholesteric liquid crystalline phase are maintained, and the liquid crystal compound in the layer need not exhibit liquid crystal properties anymore. For example, the polymerizable liquid crystal compound may have high molecular weight due to a curing reaction and may have lost the liquid crystal properties.

It is known that a cholesteric liquid crystalline phase exhibits selective reflectivity at a specific wavelength. The center wavelength 2 of selective reflection (selective reflection center wavelength λ) in the general cholesteric liquid crystalline phase depends on a helical pitch P in the cholesteric liquid crystalline phase, and is based on a relationship between an average refractive index n of the cholesteric liquid crystalline phase and λ=n×P. Therefore, the selective reflection center wavelength can be adjusted by adjusting the helical pitch. In the selective reflection center wavelength of the cholesteric liquid crystalline phase, the length of the wavelength is larger as the helical pitch is larger.

The helical pitch is, that is, one pitch of a helical structure of the cholesteric liquid crystalline phase (a period of a helix), in other words, one turn of a helix. That is, the helical pitch is a length in a helical axial direction in which a director (the long axis direction in a case of a rod-like liquid crystal compound) of the liquid crystal compound that constitutes the cholesteric liquid crystalline phase rotates by 360°.

The helical pitch of the cholesteric liquid crystalline phase depends on a type of a chiral agent used together with the liquid crystal compound and an addition concentration of the chiral agent during the formation of the cholesteric liquid crystal layer. Therefore, a desired helical pitch can be obtained by adjusting these conditions.

That is, in a case where the cholesteric liquid crystal layer is used as the wavelength-selective reflection layer, the helical pitch of the cholesteric liquid crystalline phase need only be adjusted by adjusting the type of the chiral agent and the addition concentration of the chiral agent such that a selective reflection center wavelength of the cholesteric liquid crystal layer is within a range including the wavelength of the excitation light.

Regarding the adjustment of the pitch, detailed description can be found in FUJIFILM Research Report No. 50 (2005), p. 60 to 63. As a method of measuring a sense of helix and a helical pitch, a method described in “Introduction to Liquid Crystal Chemistry Experiment”, (the Japanese Liquid Crystal Society, 2007, Sigma Publishing Co., Ltd.), p. 46, and “Liquid Crystal Handbook” (the Editing Committee of Liquid Crystal Handbook, Maruzen Publishing Co., Ltd.), p. 196 can be used.

In addition, the cholesteric liquid crystalline phase exhibits selective reflectivity with respect to left or right circularly polarized light at a specific wavelength. Whether or not the reflected light is dextrorotatory circularly polarized light or levorotatory circularly polarized light is determined depending on a helically twisted direction (sense) of the cholesteric liquid crystalline phase. Regarding the selective reflection of circularly polarized light by the cholesteric liquid crystalline phase, dextrorotatory circularly polarized light is reflected in a case where the helical twisted direction of the cholesteric liquid crystalline phase is right, and levorotatory circularly polarized light is reflected in a case where the helical twisted direction is left. Therefore, in a case where the cholesteric liquid crystal layer is used as the wavelength-selective reflection layer, the wavelength-selective reflection layer preferably has a configuration in which the cholesteric liquid crystal layer, which reflects dextrorotatory circularly polarized light of light in a wavelength range including the wavelength of the excitation light, and the cholesteric liquid crystal layer, which reflects levorotatory circularly polarized light of light in a wavelength range including the wavelength of the excitation light, are provided.

A revolution direction of the cholesteric liquid crystalline phase can be adjusted by types of liquid crystal compounds for forming the cholesteric liquid crystal layer and/or types of added chiral agents.

In addition, in the cholesteric liquid crystal layer, a half-width Δλ (nm) of a selective reflection band (circularly polarized light reflection band) exhibiting selective reflection depends on Δn of the cholesteric liquid crystalline phase and the helical pitch P, and is based on a relationship of Δλ=Δn×P. Accordingly, a width of the selective reflection band can be controlled by adjusting the Δn. The Δn can be adjusted according to types of liquid crystal compounds for forming the cholesteric liquid crystal layer and a mixing ratio thereof, and a temperature during fixing of alignment. Therefore, a wavelength bandwidth can be adjusted by adjusting the types of liquid crystal compounds and a mixing ratio thereof, and the temperature during fixing of alignment or other conditions, thereby adjusting the half-width Δλ of the selective reflection band.

In addition, in a case where the wavelength bandwidth of the reflection layer is broadened, a configuration in which two or more cholesteric liquid crystal layers having different selective reflection wavelengths are provided may be employed. The reflection band of the reflection layer can be broadened by the configuration in which the reflection layer is formed by laminating two or more cholesteric liquid crystal layers having different selective reflection wavelengths.

### (Forming Method of Cholesteric Liquid Crystal Layer)

A forming method of the cholesteric liquid crystal layer is not particularly limited, and the cholesteric liquid crystal layer may be formed by various known methods. For example, the cholesteric liquid crystal layer can be formed according to the following procedure of: coating a support or an underlayer formed on the support with a liquid crystal composition obtained by the dissolution of a liquid crystal compound, a chiral agent, a polymerization initiator, a surfactant added as necessary, and the like in a solvent; drying the liquid crystal composition to obtain a coating film; aligning the liquid crystal compound in the coating film; and irradiating this coating film with an actinic ray to cure the liquid crystal composition.

In addition, in a case where the wavelength-selective reflection layer has a configuration in which a plurality of cholesteric liquid crystal layers are provided, the wavelength-selective reflection layer having a configuration in which the plurality of cholesteric liquid crystal layers are laminated need only be formed by forming each of the cholesteric liquid crystal layers on the support and then peeling and bonding the cholesteric liquid crystal layers. Alternatively, a wavelength-selective reflection layer having a configuration in which the plurality of cholesteric liquid crystal layers are laminated may be formed by forming a first cholesteric liquid crystal layer on the support and then sequentially forming the next cholesteric liquid crystal layer on the previously formed cholesteric liquid crystal layer.

### (Liquid Crystal Compound)

The liquid crystal compound used for forming the cholesteric liquid crystal layer is not limited, and various known rod-like liquid crystal compounds and disk-like liquid crystal compounds are used. Furthermore, a polymerizable liquid crystal compound is preferable.

Examples of the liquid crystal compound include each of compounds described in Makromol. Chem., vol. 190, p. 2255 (1989); Advanced Materials, vol. 5, p. 107 (1993); specifications of U.S. Pat. No. 4,683,327A, U.S. Pat. No. 5,622,648A, and U.S. Pat. No. 5,770,107A; WO1995/22586A, WO1995/24455A, WO1997/00600A, WO1998/23580A, WO1998/52905A, WO2016/194327A, and WO2016/052367A; JP1989-272551A (JP-H01-272551A), JP1994-16616A (JP-H06-16616A), JP1995-110469A (JP-H07-110469A), JP1999-80081A (JP-H11-80081A), and JP2001-328973A; and other specifications.

The liquid crystal composition may contain two or more types of liquid crystal compounds.

A content of the liquid crystal compound contained in the liquid crystal composition is not particularly limited, but is preferably 80%to 99.9% by mass, more preferably 84% to 99.5% by mass, and still more preferably 87%to 99% by mass with respect to the mass of solid content (the mass excluding a solvent) in the liquid crystal composition. (Chiral agent)

As the chiral agent, various known chiral agents can be used.

The chiral agent has a function of inducing a helical structure of a cholesteric liquid crystalline phase to be formed. The chiral agent may be selected according to the purpose because induced helical senses or pitches are different depending on chiral agents. A force with which the chiral agent induces the helical structure of the cholesteric liquid crystalline phase is called helical twisting power (HTP). In a case where chiral agents having the same concentration are used, a helical pitch is smaller as a chiral agent has a larger HTP.

Examples of the chiral agent include compounds described in Liquid Crystal Device Handbooks (Chapter 3, Section 4-3, Chiral Agents for TN and STN, p. 199, edited by Japan Society for the Promotion of Science, 142 Committee, 1989), and JP2003-287623A, JP2002-302487A, JP2002-80478A, JP2002-80851A, JP2010-181852, and JP2014-034581A.

The chiral agent generally includes asymmetric carbon atoms. However, an axially asymmetric compound or a planar asymmetric compound, which does not have asymmetric carbon atoms, can also be used as a chiral agent. Examples of the axially asymmetric compound or the planar asymmetric compound include binaphthyl, helicene, paracyclophane, and derivatives thereof. The chiral agent may include a polymerizable group.

In a case where both the chiral agent and the liquid crystal compound have a polymerizable group, a polymer which includes a repeating unit induced from the polymerizable liquid crystal compound and a repeating unit induced from the chiral agent can be formed by a polymerization reaction of a polymerizable chiral agent and the polymerizable liquid crystal compound. In this aspect, the polymerizable group contained in the polymerizable chiral agent is preferably the same group as the polymerizable group contained in the polymerizable liquid crystal compound.

In addition, the chiral agent may be a liquid crystal compound. In addition, the chiral agent may be a chiral agent with HTP changing by the occurrence of return isomerization, dimerization, isomerization and dimerization, and the like upon irradiation with light.

A content of the chiral agent in the liquid crystal composition is preferably 0.01% to 200% by mol and more preferably 1% to 30% by mol, with respect to the total molar amount of the liquid crystal compound.

### (Other Additives)

The liquid crystal composition may further contain, as necessary, a polymerization initiator, a crosslinking agent, an alignment control agent, a surfactant, a polymerization inhibitor, an antioxidant, an ultraviolet absorber, a light stabilizer, a coloring material, metal oxide fine particles and the like within a range in which the optical performance does not deteriorate. In addition, the liquid crystal composition may include a solvent.

### <RGB Reflection Layer>

The RGB reflection layer 14 reflects at least light having a wavelength of 450 nm to 650 nm, and is disposed on a LED array 12 side with respect to the color conversion layer 16. In the example shown in FIG. 1, the RGB reflection layer 14 is disposed between the color conversion layer 16 and the LED array 12. In this case, the RGB reflection layer 14 transmits light having the wavelength of the excitation light. That is, the RGB reflection layer 14 is a wavelength-selective reflection layer that selectively reflects light having a wavelength of 450 nm to 650 nm and transmits light having the wavelength of the excitation light, for example, light having a wavelength of less than 420 nm, and is a visible light reflection layer.

By disposing the RGB reflection layer 14 that transmits the excitation light and reflects the light having the wavelength, at which each conversion region emits light, between the color conversion layer 16 and the LED array 12, among the light emitted in all directions by exciting each conversion region of the color conversion layer 16, the light emitted to the LED array 12 side can be reflected toward the emission side (a display surface side of the LED display device) to increase the utilization efficiency of light.

In addition, since the RGB reflection layer 14 transmits light having the wavelength of the excitation light, the excitation light emitted by the LED array 12 can be transmitted and incident on the color conversion layer 16 (each conversion region).

In addition, the RGB reflection layer 14 is disposed at the positions corresponding to the red color conversion region 30R, the green color conversion region 30G, and the blue color conversion region 30B in the plane direction, and the RGB reflection layer 14 at each position is integrally formed. That is, the RGB reflection layer 14 is disposed to cover the red color conversion region 30R, the green color conversion region 30G, and the blue color conversion region 30B, and is also disposed at a position of the partition wall that divides cach conversion region. The RGB reflection layer 14 has the same characteristics for reflection and transmission at the position corresponding to the red color conversion region 30R, the position corresponding to the green color conversion region 30G, and the position corresponding to the blue color conversion region 30B. Therefore, the RGB reflection layer 14 reflects the light having a wavelength at which the red color conversion region 30R emits light, the light having a wavelength at which the green color conversion region 30G emits light, and the light having a wavelength at which the blue color conversion region 30B emits light.

As the RGB reflection layer that selectively reflects light emitted from each conversion region (hereinafter, also referred to as visible light), a cholesteric liquid crystal layer formed by fixing a cholesteric liquid crystalline phase or a laminate in which a layer of high refractive index and a layer of low refractive index are alternately laminated in a plurality of layers (so-called dielectric multi-layer film) is suitably used.

As described above, the wavelength at which the dielectric multi-layer film reflects and the reflectivity of the dielectric multi-layer film can be adjusted by a difference in refractive indices between the layer of low refractive index and the layer of high refractive index, a thickness, layers to be laminated, and the like. Therefore, in a case where the dielectric multi-layer film is used as the wavelength-selective reflection layer that reflects visible light, a difference in refractive indices between the layer of low refractive index and the layer of high refractive index, a thickness, layers to be laminated, and the like need only be adjusted such that a selective reflection center wavelength of the dielectric multi-layer film is within a range including a wavelength of visible light. In addition, the RGB reflection layer may have, for example, a configuration in which an R reflection layer that reflects red light emitted from the red color conversion region 30R, a G reflection layer that reflects green light emitted from the green color conversion region 30G, and a B reflection layer that reflects blue light emitted from the blue color conversion region 30B are provided. In this case, a difference in refractive indices between the layer of low refractive index and the layer of high refractive index, a thickness, layers to be laminated, and the like of the dielectric multi-layer film as each reflection layer need only be adjusted to set the selective reflection center wavelength of each reflection layer within a desired range. In a case where the RGB reflection layer has a configuration in which a plurality of dielectric multi-layer films are provided, the RGB reflection layer need only be produced by forming each dielectric multi-layer film and then bonding the dielectric multi-layer films to each other. Alternatively, the thickness may be adjusted before the process such that a plurality of different dielectric multi-layer films are formed, thereby integrally forming the plurality of dielectric multi-layer films by stretching, extrusion molding, and the like.

As described above, the wavelength (selective reflection center wavelength) 2 at which the cholesteric liquid crystal layer reflects light depends on the helical pitch P in the cholesteric liquid crystalline phase. Therefore, in a case where the cholesteric liquid crystal layer is used as the RGB reflection layer, the helical pitch of the cholesteric liquid crystalline phase need only be adjusted by adjusting the type of the chiral agent and the addition concentration of the chiral agent such that the selective reflection center wavelength of the cholesteric liquid crystal layer is within a range including the wavelength of the excitation light. In addition, the RGB reflection layer may have, for example, a configuration in which a cholesteric liquid crystal layer that reflects red light emitted from the red color conversion region 30R, a cholesteric liquid crystal layer that reflects green light emitted from the green color conversion region 30G, and a cholesteric liquid crystal layer that reflects blue light emitted from the blue color conversion region are provided. In this case, the helical pitch of the cholesteric liquid crystalline phase need only be adjusted by adjusting the type of the chiral agent and the addition concentration of the chiral agent in the case of forming each cholesteric liquid crystal layer such that the selective reflection center wavelength of each cholesteric liquid crystal layer is within a desired range.

In addition, as described above, the cholesteric liquid crystal layer exhibits selective reflectivity with respect to either dextrorotatory or levorotatory circularly polarized light at a specific wavelength. Therefore, for example, it is preferable that the RGB reflection layer has a configuration in which a cholesteric liquid crystal layer that reflects dextrorotatory circularly polarized light of red light emitted from the red color conversion region 30R, a cholesteric liquid crystal layer that reflects levorotatory circularly polarized light of red light emitted from the red color conversion region 30R, a cholesteric liquid crystal layer that reflects dextrorotatory circularly polarized light of green light emitted from the green color conversion region 30G, a cholesteric liquid crystal layer that reflects levorotatory circularly polarized light of green light emitted from the green color conversion region 30G, a cholesteric liquid crystal layer that reflects dextrorotatory circularly polarized light of blue light emitted from the blue color conversion region, and a cholesteric liquid crystal layer that reflects levorotatory circularly polarized light of blue light emitted from the blue color conversion region are provided.

As described above, in a case of the configuration in which the first functional layer (wavelength-selective reflection layer) that reflects the light source light (excitation light) and transmits the long-wavelength light (visible light) and the second functional layer (reflection layer) that reflects the long-wavelength light (visible light) are provided in a divided manner for the plurality of LED elements, there is a problem that the number of the components is large, the structure is complicated, and the number of manufacturing processes is large.

On the other hand, the LED display device according to the embodiment of the present invention includes the wavelength-selective reflection layer 18 that is disposed on a side of the color conversion layer 16 opposite to the LED array 12, and the RGB reflection layer 14 that is disposed on the LED array 12 side with respect to the color conversion layer 16, and has a configuration in which a height h of the partition wall 32 of the color conversion layer 16 is 20 μm or less and a ratio w/h of a width w between the partition walls 32 to the height h (hereinafter, also referred to as an aspect ratio) is 2 or more, and the wavelength-selective reflection layer 18 selectively reflects the light having the wavelength of the excitation light and is integrally formed at positions corresponding to the red color conversion region, the green color conversion region, and the blue color conversion region.

By adopting the configuration in which the wavelength-selective reflection layer 18 integrally formed at the positions corresponding to the red color conversion region, the green color conversion region, and the blue color conversion region is provided, the excitation light transmitted through the color conversion layer 16 can be reflected toward the color conversion layer 16 and can be incident on the color conversion layer 16 again, so that conversion efficiency of light can be increased. Therefore, the height h of the partition wall 32 of the color conversion layer 16 and the aspect ratio w/h can be set within the above-described ranges, that is, the height of the partition wall 32 can be lowered and the aspect ratio can be increased. Therefore, a quantity by which the partition wall absorbs light emitted in all directions by exciting the conversion region can be reduced, and the decrease in the utilization efficiency of light can be prevented. In addition, since the wavelength-selective reflection layer 18 is integrally formed at the positions corresponding to the red color conversion region, the green color conversion region, and the blue color conversion region, the number of components can be reduced, and the structure can be simplified. Therefore, the number of manufacturing processes can also be reduced.

From the viewpoint of the utilization efficiency of light, the height h of the partition wall 32 is preferably 100 μm or less, and more preferably 5 μm to 10 μm.

From the viewpoint of utilization efficiency of light, the aspect ratio w/h is preferably 2 or more, more preferably 2 to 7, and still more preferably 4 to 6.

Here, as in the example shown in FIG. 1, by adopting a configuration in which the RGB reflection layer 14 is disposed at the positions corresponding to the red color conversion region 30R, the green color conversion region 30G, and the blue color conversion region 30B in the plane direction, and the RGB reflection layer 14 at each position is integrally formed, the number of components can be reduced, and the structure can be simplified.

In addition, the thickness of the wavelength-selective reflection layer 18 is preferably 10 μm or less, more preferably 5 μm to 1 μm, and still more preferably 3 μm to 1 μm.

In a case of a configuration in which the wavelength-selective reflection layer 18 is integrally provided, the wavelength-selective reflection layer 18 is also disposed on the partition wall 32. In this case, in a case where the excitation light emitted from the LED 22 corresponding to a certain subpixel is reflected by the wavelength-selective reflection layer 18, there is a concern that crosstalk in which light leaks to a conversion region corresponding to an adjacent subpixel may occur. In a case where the crosstalk occurs, the brightness (quantity of light) of each subpixel is changed, and the color reproducibility is deteriorated.

Regarding the above, by setting the thickness of the wavelength-selective reflection layer 18 to 10 μm or less, it is possible to suppress the occurrence of the crosstalk even in a configuration in which the wavelength-selective reflection layer 18 is integrally provided.

From the viewpoint of making the thickness of the wavelength-selective reflection layer 18 thinner, the wavelength-selective reflection layer 18 is preferably a cholesteric liquid crystal layer.

In addition, an interval between the wavelength-selective reflection layer 18 and the partition wall 32 in a thickness direction is preferably 5 μm or less, more preferably 2 μm or less, and still more preferably 1 μm to 0.1 μm.

In the LED display device 10, each member to be laminated may be adhered by an adhesive or a pressure sensitive adhesive. In a case where the wavelength-selective reflection layer 18 and the color conversion layer 16 are adhered to each other with an adhesive or the like, an interval between the wavelength-selective reflection layer 18 and the partition wall 32 is generated by a thickness of an adhesive layer. There is a concern that crosstalk in which light leaks to an adjacent subpixel occurs in a case where the interval between the wavelength-selective reflection layer 18 and the partition wall 32 is too large.

Regarding the above, by setting the interval between the wavelength-selective reflection layer 18 and the partition wall 32 in the thickness direction to 5 μm or less, it is possible to suppress the occurrence of the crosstalk.

The present invention is not limited to a configuration in which the wavelength-selective reflection layer 18 and the color conversion layer 16 are adhered to cach other with an adhesive or the like, and a configuration in which the wavelength-selective reflection layer 18 and the color conversion layer 16 are disposed directly in contact with each other may be adopted.

In addition, the thickness of the RGB reflection layer 14 is preferably 40 μm or less, more preferably 30 μm or less, and still more preferably 20 μm to 5 μm.

In a case of the configuration in which the RGB reflection layer 14 is integrally provided, the RGB reflection layer 14 is also disposed at a position of the partition wall 32. In this case, in a case where light emitted from a conversion region corresponding to a certain subpixel is reflected by the RGB reflection layer 14, there is a concern that crosstalk in which light leaks to an adjacent subpixel may occur.

Regarding the above, by setting the thickness of the RGB reflection layer 14 to 40 μm or less, it is possible to suppress the occurrence of the crosstalk even in a configuration in which the RGB reflection layer 14 is integrally provided.

From the viewpoint of making the thickness of the RGB reflection layer 14 thinner, the RGB reflection layer 14 is preferably a cholesteric liquid crystal layer.

Here, in the example shown in FIG. 1, a configuration in which the RGB reflection layer 14 is disposed between the color conversion layer 16 and the LED array 12 is adopted, but the present invention is not limited thereto. The LED display device according to the embodiment of the present invention may has a configuration in which the reflection layer is disposed on at least a part of a position other than a region, in which the light emitting diode is disposed, on a surface on which the light emitting diode is disposed, and reflects at least light having a wavelength of 380 nm to 650 nm.

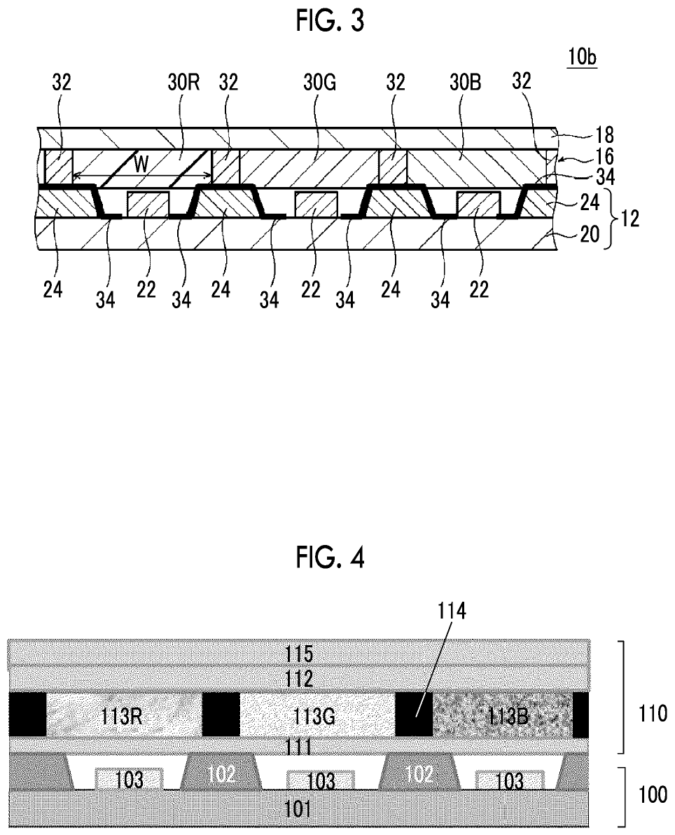

FIG. 3 is a diagram conceptually showing another example of the LED display device according to the embodiment of the present invention.

An LED display device 10b shown in FIG. 3 includes the LED array 12, an RGB reflection layer 34, the color conversion layer 16, and the wavelength-selective reflection layer 18 in this order. The LED array 12, the color conversion layer 16, and the wavelength-selective reflection layer 18 have the same configurations as that of the LED array 12, the color conversion layer 16, and the wavelength-selective reflection layer 18 provided in the LED display device 10 shown in FIG. 1, and thus the description thereof will be omitted.

In the LED display device 10b shown in FIG. 3, the RGB reflection layer 34 is disposed on at least a part of a position other than a region, in which the LED 22 is disposed, on a surface of the substrate 20 of the LED array 12 on which the LED 22 is disposed. In the shown example, the RGB reflection layer 34 is disposed in contact with an upper side of the substrate 20 and the bank 24 of the LED array 12, excluding the LED 22. That is, the RGB reflection layer 34 has an opening portion having the substantially same shape as the planar shape of the LED 22 at a position corresponding to the LED 22 in a plan view, and the LED 22 is inserted into the opening portion and is disposed to cover the substrate 20 and the bank 24.

In the example shown in FIG. 3, a configuration in which the RGB reflection layer 34 is integrally formed is adopted, but the present invention is not limited thereto, and for example, the RGB reflection layer 34 may be provided for each subpixel. From the viewpoint that the number of components can be reduced and the structure can be simplified, it is preferable that the RGB reflection layer 34 is integrally formed.

In addition, the RGB reflection layer 34 reflects at least light having the wavelength of 380 nm to 650 nm. That is, the RGB reflection layer 34 is a reflection layer that reflects the excitation light and the visible light.

The RGB reflection layer 34 reflects the excitation light, and thus the excitation light further transmitted through the conversion region without being subject to the wavelength conversion, among the excitation light that is emitted from the LED 22 and incident on the conversion region, is reflected by the wavelength-selective reflection layer 18, and is incident on the conversion region again, can be reflected toward the conversion region again. Therefore, the conversion efficiency of light can be further improved.

In addition, the RGB reflection layer 34 reflects the visible light, and thus the utilization efficiency of light can be increased by reflecting the light, which is traveling toward the LED array 12 side, toward the emission side (the display surface side of the LED display device) among the light emitted in all directions by exciting each conversion region of the color conversion layer 16.

As the RGB reflection layer 34, a cholesteric liquid crystal layer or a dielectric multi-layer film, which is adjusted to reflect at least light having the wavelength of 380 nm to 650 nm, can be used. Alternatively, a metal foil having a high reflectivity, such as an aluminum foil and a silver foil, may be used.

### EXAMPLES

Hereinafter, the present invention will be described in more detail with reference to examples. Materials, an amount and a ratio of the materials used, how to treat the materials, a treatment procedure, and the like shown in the following examples can be appropriately changed as long as the gist of the present invention is maintained. Therefore, the scope of the present invention should not be construed as being limited to the examples shown below.

### Examples

### <Configuration of Display Device 1>

FIG. 4 schematically shows a configuration of an LED display device (display device 1) according to an example of the present invention. The display device 1 is a display device using a micro LED, and includes an LED array substrate 100 and a color conversion substrate 110.

Configurations of each unit of the display device 1 will be described.

### <<LED Array Substrate>>

The LED array substrate 100 includes a plurality of LED elements 103 and an element separation region (bank) 102 on a substrate 101. The LED elements 103 are disposed in a matrix form, and an element separation region 102 is provided between the LED elements 103.

In addition, the LED element 103 radiates the excitation light having a peak wavelength of 385 nm by the driving circuit.

The LED element 103 corresponds to the subpixel of the display device 1.

The element separation region 102 is formed of a black photosensitive material forming a black matrix.

### <<Color Conversion Substrate>>

The color conversion substrate 110 includes a substrate 115, a wavelength-selective reflection layer 112, a partition wall 114, wavelength conversion regions (red color conversion region 113R, green color conversion region 113G, and blue color conversion region 113B), and an RGB reflection layer 111.

The partition wall 114 is also formed of a black pigment or a black dye, similarly to the element separation region 102.

The wavelength conversion regions (113R, 113G, and 113B) include a substance that converts the wavelength of the light radiated from the LED element 103 into each of the red, green, and blue wavelength ranges, and a binder. In the example, a phosphor was used as the wavelength conversion substance. An absorbance of the excitation light varies depending on the thickness of the wavelength conversion layer, but here, levels of 10 um, 20 um, and 30 um were provided in accordance with the height of the partition wall.

The wavelength-selective reflection layer 112 transmits light emitted from the wavelength conversion regions (113R, 113G, 113B) and reflects the excitation light emitted from the LED element 103.

The wavelength-selective reflection layer 112 is integrally formed on the wavelength conversion regions (113R, 113G, and 113B).

The RGB reflection layer 111 is a wavelength-selective reflection layer that transmits the excitation light emitted from the LED element 103 and reflects the light emitted from the wavelength conversion layers (113R, 113G, and 113B).

The substrate 115 is a cover that is disposed on a visible side of the wavelength-selective reflection layer 112 and protects each member.

The substrate 115 may be provided with a UV absorbing layer for preventing excitation by external light and for absorbing and cutting the excitation light. Alternatively, a film containing the UV absorbing material may be used as a base material.

### <Operation of Display Device 1>

The operation of the LED display device of the present example will be described. This is substantially the same in the display device 1 and a display device 2.

In a case where the excitation light is emitted from the LED elements 103 arranged on the substrate 101, the excitation light is transmitted through the RGB reflection layer 111 and reaches the wavelength conversion regions (113R, 113G, and 113B). A part of the excitation light (in the example, about half of the excitation light) is absorbed by wavelength conversion materials (phosphor), and each material emits light having a wavelength corresponding to RGB. The light emission is light emission in all directions.

Among the light, the light traveling in an upward direction of FIG. 4 is transmitted through the wavelength-selective reflection layer 112 and is emitted to the visible side. The light traveling downward is reflected by the RGB reflection layer 111 and then emitted in the upward direction.

The light traveling in a lateral direction is absorbed or scattered by the partition wall 114 to become stray light.

The excitation light that has not been completely absorbed by the wavelength conversion layer and has passed through the wavelength conversion layer is reflected by the upper wavelength-selective reflection layer 112 and returned to the wavelength conversion regions (113R, 113G, and 113B), and is absorbed again in the wavelength conversion regions and converted into RGB.

By intentionally transmitting a part of the excitation light without being converted and returning the excitation light with the RGB reflection layer, the excitation light enters from both the upper and lower sides of the wavelength conversion region, and the wavelength conversion is not biased and saturated, so that the efficiency is improved.

In addition, since the thickness of the wavelength conversion region is designed to be thin, the partition wall 114 is lowered, and thus light in lateral direction that is lost there is reduced. As a result, luminous efficacy can be significantly improved.

### <Manufacturing Method of Display Device 1>

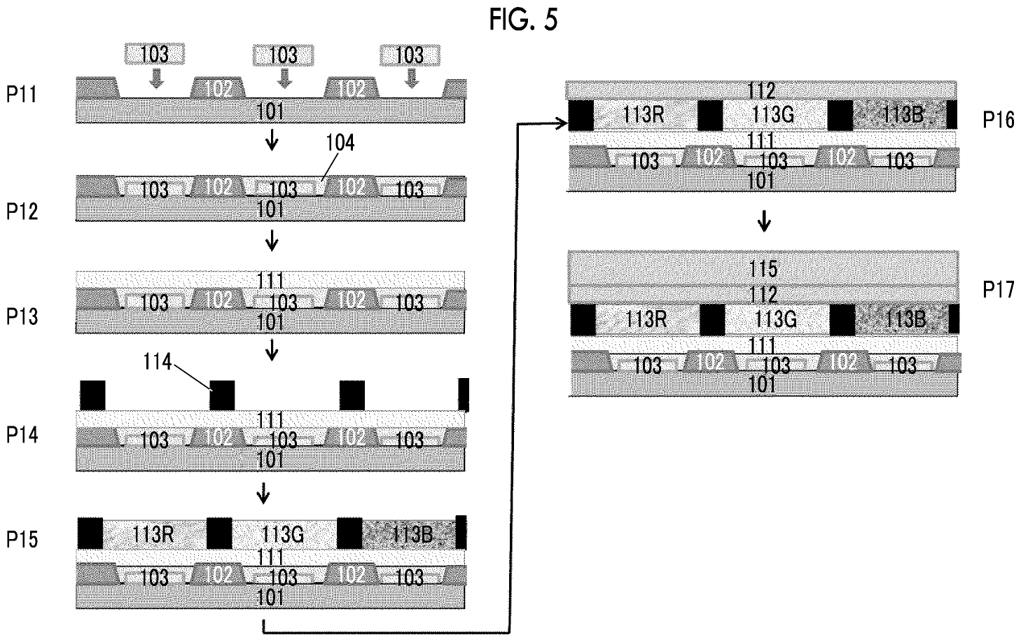

FIG. 5 shows the manufacturing process of the display device 1 in an order of P11 to P17.

(P11) The glass substrate 101 on which a drive circuit of an LED and a connection terminal of an element are arranged is coated with a photosensitive black resin material having a thickness of 8 μm, and an element separation region 102 having a predetermined shape is formed by a photolithography method. A pixel pitch was 180 μm, and an opening width w was 50 μm. A forming method of the drive circuit may be the same as a general method for an OLED display device, but here, for the sake of simplification, an anode electrode and a cathode electrode for connecting a signal line and the LED element were formed, and the electrodes of the LED element 103 were electrically bonded thereto to apply a driving current from an outside. As the LED element 103, a flip chip type having a size of 18×33 μm and a luminescence wavelength peak of 385 nm was used.

(P12) A recess portion was filled with a flattening protection transparent resin 104 using an ink jet, and flattened. Although an acrylic thermosetting resin was used as the transparent resin, an epoxy-based resin, a polyimide-based resin, or the like may be used. A UV curable resin may be used. The coating may also be performed by a method such as die coating. In addition, an inorganic transparent film such as SiO₂ or SiNₓ may be formed on this layer as a barrier film.

(P13) Transparent coating materials having a low refractive index (n=1.2)/high refractive index (n=2.3→1.85) were alternately spin-coated on this layer in 20 layers at a predetermined thickness to form an RGB reflection layer 111. A total film thickness was set to about 2 μm. In addition, the refractive index n of the high refractive index layer was changed from 2.3 to 1.85 between 20 layers. The film had optical characteristics of transmitting about 85% of light having a wavelength of 385 nm and reflecting about 95% of light having a wavelength of 410 nm to 700 nm. This layer may be formed by a method such as a vacuum sputtering method, and each parameter of low refractive index/high refractive index/layer thickness is not limited thereto.

(P14) A black photosensitive resin was applied thereon to form the partition wall 114 by a photolithography method. A partition wall width was 10 μm, and the shape was set to have an opening width of 50 μm in accordance with the element separation region 102.

A height h of the partition wall (114) was produced with coating thicknesses of levels of 10 μm, 20 μm, and 30 μm.

(P15) The space (cavity) surrounded by the partition wall 114 was filled with the color conversion material corresponding to each color of RGB by an ink jet method. In this filling step, instead of the ink jet, the color conversion material may be mixed with the photosensitive resin material and the resin material may be cured by irradiation with ultraviolet light, and then the unnecessary portions may be removed by washing.

(P16) A wavelength-selective reflection layer 112 of the excitation light was formed on the color conversion region. The wavelength-selective reflection layer 112 was transferred by forming a film in which a cholesteric liquid crystal was twisted and aligned at a predetermined pitch on a film support (JP5693027B), adhering the film to the color conversion region, and then peeling off the support. The film had optical characteristics of transmitting about 90% of light having a wavelength of 410 nm to 700 nm and reflecting about 90% of light having a wavelength of 385 nm. The thickness was 5 μm.

(P17) The LED display device was produced by bonding a transparent TAC film containing a UV absorbing material as the substrate (cover) 115.

### <Configuration of Display Device 2>

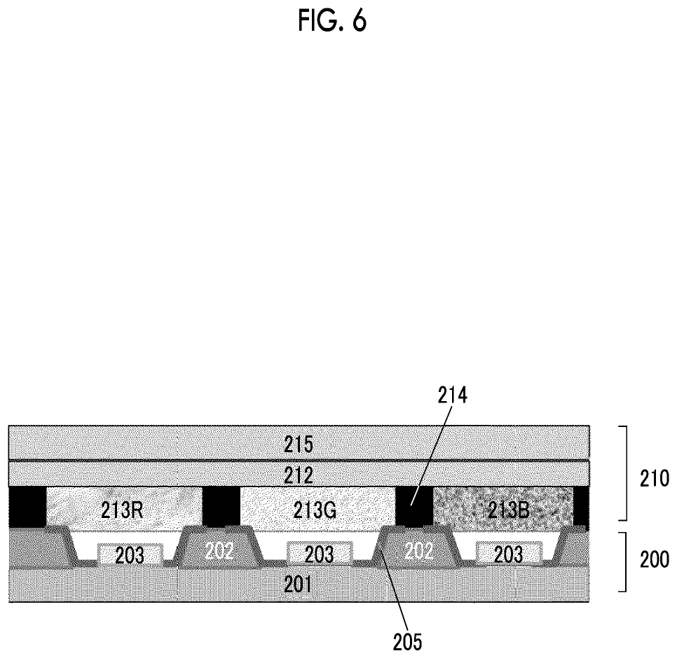

FIG. 6 schematically shows a configuration of the LED display device (display device 2) according to an example of the present invention. The display device 2 is a display device using a micro LED, and includes an LED array substrate 200 and a color conversion substrate 210. In the display device 2, a mirror reflection plate 205 is disposed on a LED array substrate 200 side instead of the RGB reflection layer 111 in the display device 1. The mirror reflection plate 205 is an RGB reflection layer according to the embodiment of the present invention.

The display device 2 reflects the excitation light emitted from the LED element 203 in the lateral direction by the mirror reflection plate 205 toward the visible side to improve the efficiency, as in the display device 1. In addition, the conversion light emitted from the color conversion region (213R, 213G, 213B) in a light source direction is reflected toward the visible side to improve the efficiency.

### <Manufacturing Method of Display Device 2>

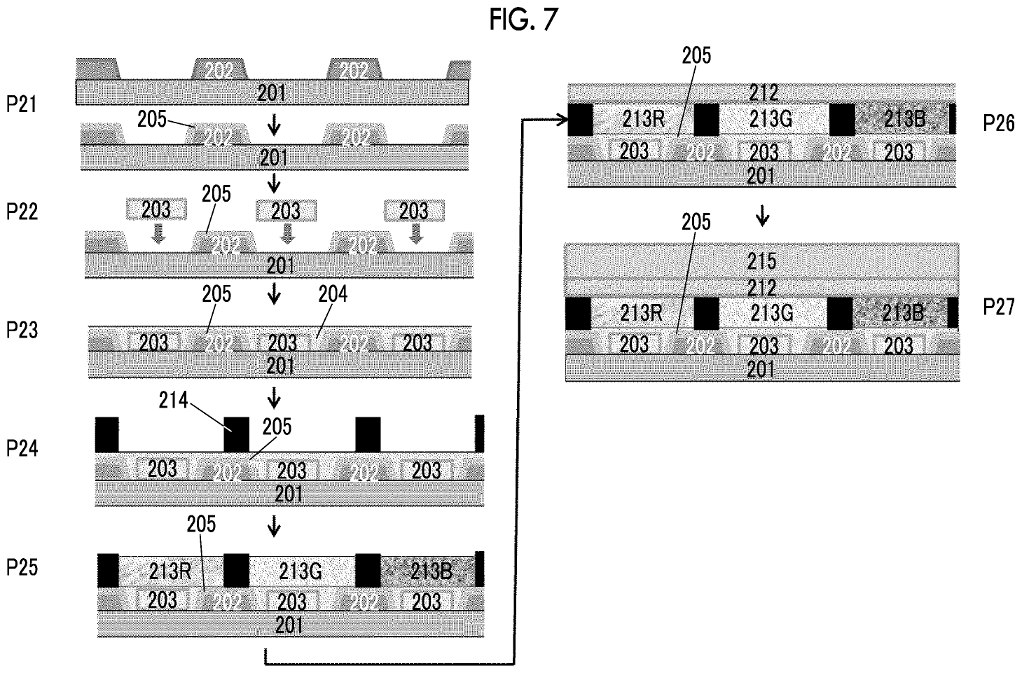

P21 to P27 in FIG. 7 show a manufacturing process of the display device 2 in order.

(P21) The glass substrate 201 on which a drive circuit of an LED and a connection terminal of an element were arranged was coated with a photosensitive black resin material having a thickness of 8 um, and an element separation region 202 was formed by a photolithography method. A shape of the element separation region was set to have a pixel pitch of 180 μm and an opening width w of 50 μm. Next, a rectangular mirror reflection plate 205 was formed of an aluminum thin film having a thickness of 0.1 μm on the element separation region 202 by using a lift-off process. The mirror reflection plate may be formed of another metal material having a high reflectivity, such as silver.

(P22) The LED element 203 was bonded to the substrate 201. The drive circuit may be formed by the same method as that for a general OLED display device, but here, for the sake of simplification, an anode electrode and a cathode electrode for connecting a signal line and the LED element were provided, and the electrodes of the flip-chip type LED element 203 were electrically bonded thereto to apply a driving current from an outside.

(P23) A recess portion was filled with a flattening transparent resin 204 using an ink jet, and flattened. Although an acrylic thermosetting resin was used as the transparent resin, an epoxy-based resin, a polyimide-based resin, or the like may be used, or a UV curable resin may be used. The coating may also be performed by a method such as die coating. In addition, an inorganic transparent film such as SiO₂ or SiNₓ may be formed on the layer as a barrier film.

(P24) A black photosensitive resin was applied thereon to form the partition wall 214 by a photolithography method. The size and the pitch were set to have a partition wall width of 10 um in accordance with the element separation region 202. The height of the partition wall was set to 10 μm, 20 μm, and 30 μm to produce three types of the partition walls.

(P25) The space (cavity) surrounded by the partition wall 214 was filled with the color conversion material corresponding to each color of RGB by an ink jet method. In this filling step, instead of the ink jet, the color conversion material may be mixed with the photosensitive resin material and the resin material may be cured by irradiation with ultraviolet light, and then the unnecessary portions may be removed by washing.

(P26) A wavelength-selective reflection layer 212 was formed on the color conversion region. The wavelength-selective reflection layer 212 was transferred by forming a film in which a cholesteric liquid crystal was twisted and aligned at a predetermined pitch on a film support (JP5693027B), adhering the film to the color conversion region, and then peeling off the support. The film had optical characteristics of transmitting about 90% of light having a wavelength of 410 nm to 700 nm and reflecting about 90% of light having a wavelength of 385 nm. The thickness was 5 μm.

(P27) The LED display device was produced by bonding a transparent TAC film containing a UV absorbing material as the substrate (cover) 215.

### <Configuration of Display Device 3>

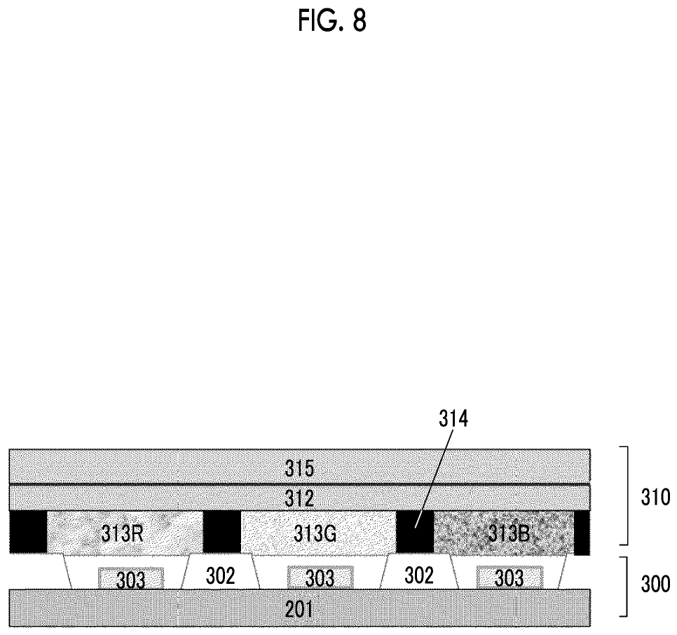

FIG. 8 schematically shows a configuration of the LED display device (display device 3) according to an example of the present invention. The display device 3 is a display device using a micro LED, and includes an LED array substrate 300 and a color conversion substrate 310. An element separation region 302 formed of a white resin is disposed instead of the RGB reflection layer 111 in the display device 1. That is, the element separation region 302 can reflect at least light having a wavelength of 450 nm to 650 nm, and has a function as the RGB reflection layer according to the embodiment of the present invention. As a result, the excitation light emitted from the LED element 303 in the lateral direction is scattered by a side wall of the element separation region 302 to improve the efficiency. In addition, the conversion light emitted from the color conversion region (313R, 313G, 313B) in the light source direction is reflected toward the visible side to improve the efficiency. The number of manufacturing processes is smaller as compared with that of the display device 2, and the productivity is good.

### <Manufacturing Method of Display Device 3>

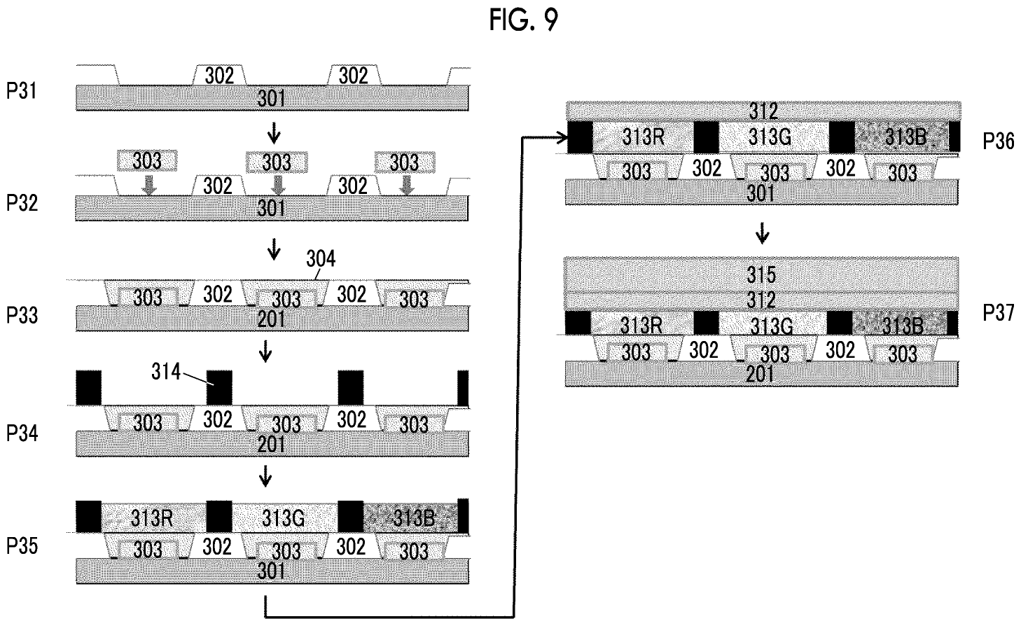

P31 to P37 in FIG. 9 show a manufacturing process of the display device 3 in order.

(P31) The glass substrate 301 on which a drive circuit of an LED and a connection terminal of an element were arranged was coated with a photosensitive white resin material having a thickness of 8 μm, and the element separation region 302 was formed by a photolithography method. Specifically, a substrate on which wiring for disposing the LED was performed was coated with a photosensitive white photoresist by die coating, and pre-baking was performed. Thereafter, exposure and development were performed using a photo mask on which a disposition pattern of the element separation region was formed, and then the main baking was performed to form the element separation region 302. A shape of the element separation region was set to have a pixel pitch of 180 μm and an opening width w of 50 μm.

LED display devices were produced in P32 to P37 in the same manner as in P22 to P27.

### <Configuration of Display Device 4 of Comparative Example (Related Art)>

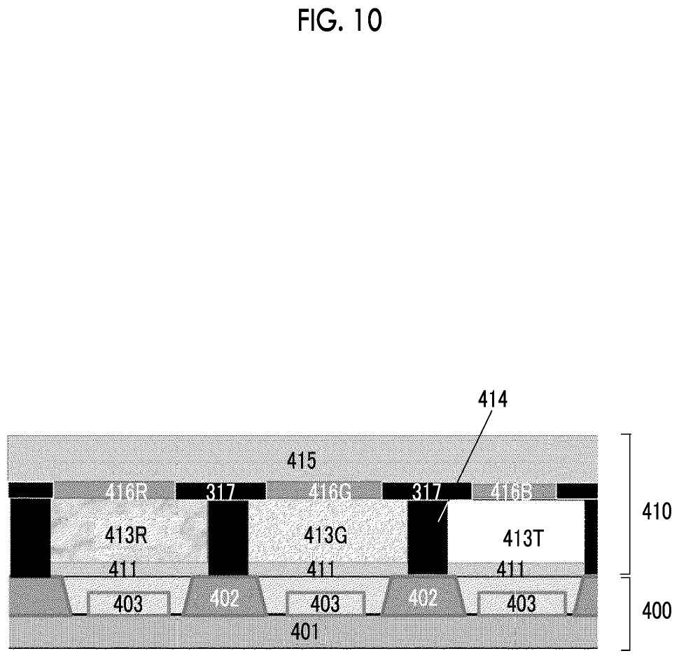

FIG. 10 is a schematic cross-sectional view showing an example of an LED display device using a Micro LED according to the related art. The LED display device is a micro-LED display device using a blue-LED as an excitation light source, and JP2021-113977A was referred to for the configuration.

Configurations of each unit of the display device 4 will be described.

The LED array substrate 400 includes a plurality of LED elements 403 and an element separation region 402 on a substrate 401. The LED element 403 uses a wavelength of about 450 nm as a luminescence wavelength. The element separation region 402 is formed of a material that does not transmit light having a wavelength of 360 nm to 650 nm, for example, a black photosensitive material forming a black matrix. The shape was set to have a pixel pitch of 180 μm and an opening width w of 50 μm as in the examples of the present invention for comparison. The substrate 401 was formed of alkali-free glass in which a circuit for driving the LED element 403 was provided.

The color conversion substrate 410 includes a substrate 415, a black matrix 417, color filter layers (416R and 416G) transmitting red light and green light, a partition wall 414, and color conversion regions (413R and 413G). The black matrix 417 and the color filter layers (416R and 416G) are the same as color filters commonly used in a liquid crystal panel, and are formed of a color resist. Color conversion regions (413R and 413G) having thicknesses of 10 μm, 20 μm, and 30 μm as a level were prepared. A height h of the partition wall 414 was in accordance with the thicknesses. As a conversion material of the wavelength conversion layers (413R and 413G), a phosphor having an excitation wavelength of 450 nm was used. The RG reflection layer 411 was a layer that transmits Blue light emitted by the LED element 403 and reflects light emitted by the color conversion regions (413R and 413G).

### <Manufacturing Method of Display Device 4>

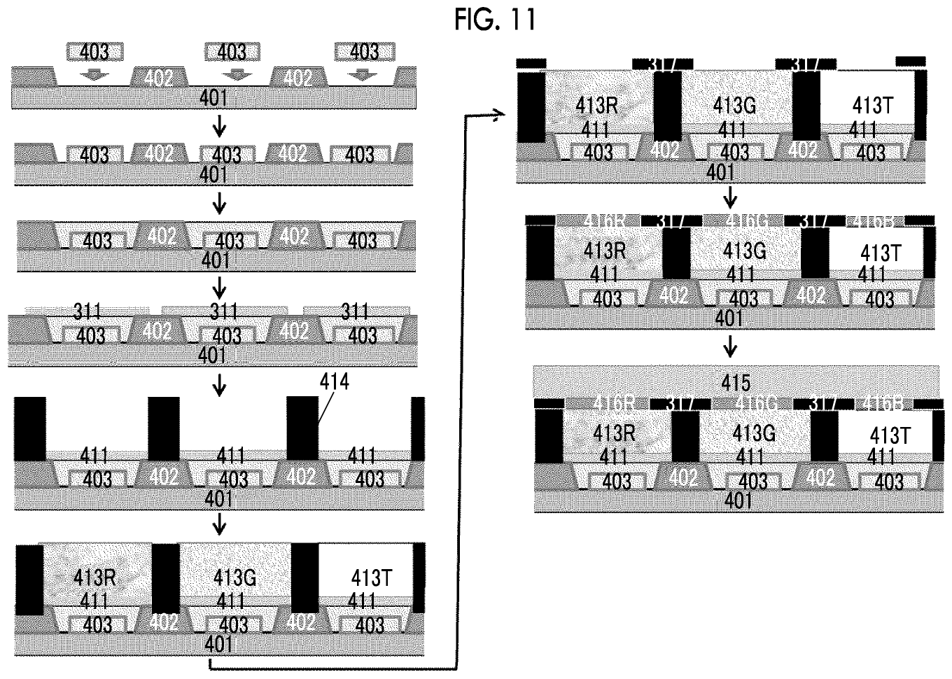

FIG. 11 shows a manufacturing process of the display device 4, which is a display device in the related art, in order. Details of the manufacturing method of the display device 4 are as described in JP2021-113977A and the like.

### <Evaluation>

In each display device produced as described above, a panel was caused to emit light with a predetermined current, and a luminance meter BM-9A was installed at a position 60 cm away from a device surface, and the luminance (referred to as luminance 1) of a region of φ1.8 mm (225 pixels) at a measurement angle of 0.2 degrees was measured.

A light source substrate on which the same LED chips as LED chips (luminescence wavelength of 385 nm and 450 nm) of the device were disposed on a glass substrate whose back surface was mirror-treated in accordance with the pixel pitch of the display device was prepared and disposed in the integrating sphere, the light source substrate was caused to emit light at the same current as described above, and the luminance (luminance 2) was measured.

A ratio of the two values of measured luminance (luminance 1/luminance 2) was calculated, and the light extraction efficiency was calculated.

Furthermore, the total efficiency was calculated by multiplying the quantum efficiency of the LED chips (385 nm and 450 nm).

Total efficiency=LED quantum efficiency×ratio of values of luminance

The results are shown in Table 1. In Table 1, V-LED represents an LED that emits ultraviolet light having a wavelength of 385 nm, B-LED represents an LED that emits blue light having a wavelength of 450 nm, V reflection F represents that the wavelength-selective reflection layer reflects ultraviolet light having a wavelength of 385 nm, and CF represents that a color filter is provided.

TABLE 1

| | | Level 1 | Level 2 | Level 3 | |
|---|---|---|---|---|---|
| Partition wall height (h) | | 10 μm | 20 μm | 30 μm | Number of |
| Opening width (w) | | 50 μm | 50 μm | 50 μm | optical |
| w/h | | 5 | 2.5 | 1.7 | system |
| | | | | | layers |
| | | | | | (processes) |
| Light extraction | V-LED + V reflection F | 0.24 | 0.18 | 0.13 | 6 |
| efficiency of | (V reflection is integrally | | | | |
| display device 1 | formed) | | | | |
| Light extraction | V-LED + V reflection F | 0.27 | 0.2 | 0.14 | 5 |
| efficiency of | (Mirror is formed on array | | | | |
| display device 2 | substrate side) | | | | |
| Light extraction | V-LED + V reflection F | 0.27 | 0.2 | 0.14 | 4 |
| efficiency of | (Pixel separation layer is | | | | |
| display device 3 | formed to be white) | | | | |
| Light extraction | B-LED + CF | 0.11 | 0.14 | 0.14 | 9 |
| efficiency of | | | | | |
| display device 4 | | | | | |

The levels 1 and 2 of the display devices 1 to 3 are LED display devices according to the embodiment of the present invention.

From the comparison between the levels 1 to 3 of each of the display devices 1 to 3, it can be seen that the light extraction efficiency is good in a case where the thickness of the partition wall is changed such that the value of ratio w/h is 2 or more.

In addition, from the comparison between the display devices 1 to 3 and the display device 4, it can be seen that the configuration according to the embodiment of the present invention has a small number of components, and thus can be produced in a small number of processes.

The display device 2 has the mirror reflection plate 205 instead of the RGB reflection layer 111 as compared with the display device 1, so that the thickness is reduced, which is preferable. In addition, the display device 2 is preferable in that there is no gap between the partition wall 214 and the element separation region 202 and there is no leaking light to adjacent pixels.

The display device 3 is preferable from the viewpoint that, in addition to the effect of the display device 2, since the element separation region 303 itself plays a role of the RGB reflection layer, it is not necessary to separately form the element separation region and the RGB reflection layer, and the number of the manufacturing processes is reduced.

### [Evaluation of Leaking Light]

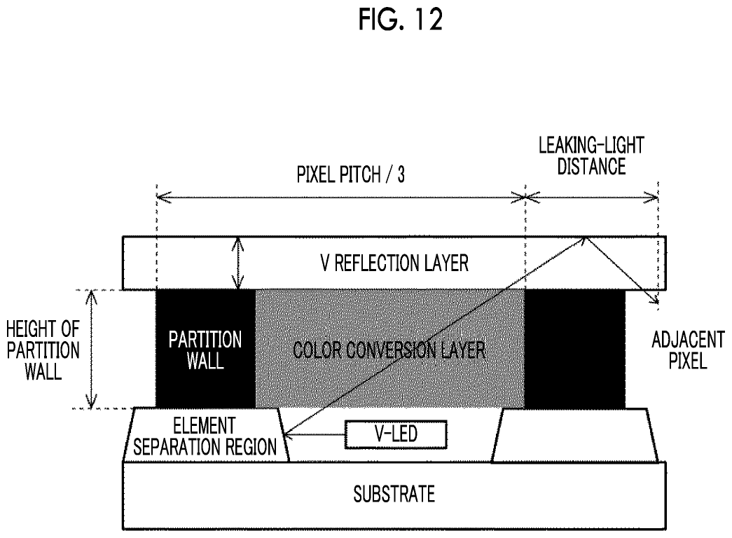

In the display device 1, the leaking-light distance (theoretical value) in a case where the thickness of the wavelength-selective reflection layer was changed to the value shown in Table 2 was calculated, and then a pixel portion was observed in a state where the panel was turned on to examine the state of the leaking light. The leaking-light distance (theoretical value) is a value of a portion shown in FIG. 12.

The state of the leaking light was evaluated based on the following criteria.
A: no light leak
B: slight light leak
C: large light leak

The results are shown in Table 2.

TABLE 2

| | Display device 1 | | | | |
|---|---|---|---|---|---|
| Partition wall height (h) | 20 μm | 20 μm | 20 μm | 20 μm | 20 μm |
| Opening width (w) | 50 μm | 50 μm | 50 μm | 50 μm | 50 μm |
| w/h | 2.5 | 2.5 | 2.5 | 2.5 | 2.5 |
| Thickness of | 2 | 5 | 8 | 10 | 12 |
| wavelength-selective | | | | | |
| reflection layer | | | | | |
| Leaking-light distance | 3.7 | 9.2 | 14.7 | 18.3 | 22 |
| (theoretical value um) | | | | | |
| Observation result of | A | A | A | A | B |
| leaking-light | | | | | |

From Table 2, it can be seen that, in a case where the wavelength-selective reflection layer is integrally formed and the thickness is 5 μm or less, and the condition in which w/h is two or more is satisfied, the distance of light leak is shortened by reducing the thickness, and the quantity of leaking light is reduced.

From the above results, it can be seen that the LED display device according to the embodiment of the present invention, in which the height h of the partition wall is 20 μm or less and the ratio w/h of the width w between the partition walls to the height h is 2 or more, can improve the utilization efficiency of light with a simple configuration having a small number of components.

From the above results, the effects of the present invention are clear.

### EXPLANATION OF REFERENCES

10, 10b: LED display device

12: LED array

14, 34: RGB reflection layer

16: color conversion layer

18: wavelength-selective reflection layer

20: substrate

22: light emitting diode (LED)

24: bank

30R: red color conversion region

30G: green color conversion region

30B: blue color conversion region

32: partition wall

h: height

w: width between partition walls

What is claimed is:

1. An LED display device comprising:
an LED array formed by arranging a plurality of light emitting diodes that emit excitation light having a light emission peak wavelength of less than 420 nm, on a substrate;
a color conversion layer;
a wavelength-selective reflection layer disposed on a side of the color conversion layer opposite to the LED array; and
an RGB reflection layer disposed on an LED array side with respect to the color conversion layer,
wherein the color conversion layer is disposed at each of positions corresponding to the light emitting diodes of the LED array, and includes a red color conversion region that is excited by the excitation light and emits red light, a green color conversion region that is excited by the excitation light and emits green light, a blue color conversion region that is excited by the excitation light and emits blue light, and a partition wall that divides the red color conversion region, the green color conversion region, and the blue color conversion region,
a height h of the partition wall is 20 μm or less and a ratio w/h of a width w between partition walls to the height h is 2 or more,
the wavelength-selective reflection layer selectively reflects light having a wavelength of the excitation light and is integrally formed at positions corresponding to the red color conversion region, the green color conversion region, and the blue color conversion region, and
the RGB reflection layer reflects at least light having a wavelength of 450 nm to 650 nm.

2. The LED display device according to claim 1,
wherein the RGB reflection layer is disposed between the color conversion layer and the LED array, and
the RGB reflection layer transmits the excitation light.

3. The LED display device according to claim 1,
wherein the RGB reflection layer is disposed on at least a part of a position other than a region, in which the light emitting diode is disposed, on a surface of the substrate on which the light emitting diode is disposed, and
the RGB reflection layer reflects at least light having a wavelength of 380 nm to 650 nm.

4. The LED display device according to claim 1,
wherein a thickness of the wavelength-selective reflection layer is 5 μm or less.

5. The LED display device according to claim 1,
wherein a thickness of the RGB reflection layer is 40 μm or less.

6. The LED display device according to claim 1,
wherein an interval between the wavelength-selective reflection layer and the partition wall in a thickness direction is 5 μm or less.

7. The LED display device according to claim 2,
wherein a thickness of the wavelength-selective reflection layer is 5 μm or less.

8. The LED display device according to claim 2,
wherein a thickness of the RGB reflection layer is 40 μm or less.

9. The LED display device according to claim 2,
wherein an interval between the wavelength-selective reflection layer and the partition wall in a thickness direction is 5 μm or less.

10. The LED display device according to claim 3,
wherein a thickness of the wavelength-selective reflection layer is 5 μm or less.

11. The LED display device according to claim 3,
wherein a thickness of the RGB reflection layer is 40 μm or less.

12. The LED display device according to claim 3,
wherein an interval between the wavelength-selective reflection layer and the partition wall in a thickness direction is 5 μm or less.

13. The LED display device according to claim 4,
wherein a thickness of the RGB reflection layer is 40 μm or less.

14. The LED display device according to claim 4,
wherein an interval between the wavelength-selective reflection layer and the partition wall in a thickness direction is 5 μm or less.

15. The LED display device according to claim 5,
wherein an interval between the wavelength-selective reflection layer and the partition wall in a thickness direction is 5 μm or less.
